(19) United States
(12) Patent Application Publication
(10) Pub. No.: US 2024/0213141 A1
(43) Pub. Date: Jun. 27, 2024

(54) DECOUPLING MIM CAPACITOR

(71) Applicant: INTERNATIONAL BUSINESS MACHINES CORPORATION, ARMONK, NY (US)

(72) Inventors: Tao Li, Slingerlands, NY (US); Tsung-Sheng Kang, Ballston Lake, NY (US); Kangguo Cheng, Schenectady, NY (US); Ruilong Xie, Niskayuna, NY (US)

(21) Appl. No.: 18/145,840

(22) Filed: Dec. 22, 2022

(51) Int. Cl. H01L 23/522; H01L 21/8234; H01L 23/528; H01L 27/06; H01L 29/06

(52) U.S. Cl. CPC H01L 23/5223; H01L 21/823475; H01L 23/5286; H01L 27/0629; H01L 28/91; H01L 29/0673

(57) ABSTRACT

Semiconductor structures, devices and methods of fabricating the same, including a semiconductor device that includes a backside power rail (BSPR), a source-drain (S/D) region connected to the BSPR, and a metal-insulator-metal capacitor (MIMC), where the BSPR directly connects to the MIMC by a MIMC via for backside power rail (VBPR) metal contact.

### BACKGROUND

### Technical Field

The present disclosure generally relates to a metal-insulator-metal (MIM) capacitor, and more particularly to a MIM capacitor for enhancing semiconductor device operability and interconnectivity.

### Description of the Related Art

Metal-insulator-metal (MIM) capacitors are commonly used for both precision and decoupling capacitor applications, including in the Back-end-of-line (BEOL) of semiconductor applications and devices. One beneficial application of a MIM capacitor in BEOL applications is to reduce power supply transients in relation to certain BEOL elements.

Moreover, with the continued scaling of semiconductor device architecture, the aspect of power delivery to the semiconductor devices presents some notable challenges. Namely, the interconnect lines that deliver power to the semiconductor devices can only be reduced in size so much before device performance is negatively impacted. One approach to eliminate congestion in the device design is to bury the power rails that bring power to the semiconductor devices in the substrate, rather than locating them above the semiconductor devices. Power rails configured in this manner are also referred to herein as ‘buried power rails.’

Additionally, depending on particular semiconductor configuration, proximity and integration between Front-End-Of-The-Line (FEOL) elements and other elements of the semiconductor device, including BEOL elements, is useful, e.g., to maximize overall device performance.

Thus, improved semiconductor device designs having one or more buried power rails and one or more MIM capacitors, while maximizing functional integration throughout the semiconductor device, would be useful.

### SUMMARY

According to an embodiment of the present disclosure, a semiconductor device is provided. The semiconductor device includes: a backside power rail (BSPR); a source-drain (S/D) region connected to the BSPR; and a metal-insulator-metal capacitor (MIMC), and where the BSPR directly connects to the MIMC by a MIMC via for backside power rail (VBPR) metal contact. In various embodiments, the MIMC VBPR contact is connected to at least one electrode of the MIMC (e.g., a direct connection), the source-drain region is connected to the BSPR by a VBPR S/D metal contact (e.g., direct connection), and the MIM capacitor is in a dummy region of the semiconductor device. In various embodiments, the semiconductor device can further include: a back-side power distribution network (BSPDN) directly connected with the BSPR, a middle-end-of-the-line (MOL) region including a plurality of metal contacts, where at least one electrode of the MIM capacitor is directly coupled or connected to at least one of the plurality of metal contacts of the MOL region, where the at least one MIMC electrode connected to the MIMC VBPR contact is distinct from the at least one electrode of the MIMC connected the at least one of the plurality of metal contacts of the MOL region., where the BSPR includes at least two portions, the MIMC VBPR contacts at least one of the at least two portions of the BSPR; and the VBPR S/D contacts another portion of the at least two portions of the BSPR. In one or more embodiments of the present disclosure, the inclusion of the MIMC, as described, mitigates the impact of transient currents, while storing charge associated therewith, and utilizing said charge to power FEOL components in the event of a power outage.

According to another embodiment of the present disclosure, a semiconductor device is provided. The semiconductor device includes: a back-end-of-the-line (BEOL) region; a front-end-of-the-line (FEOL) region that includes a backside power distribution network (BPDN); and a metal-insulator-metal (MIM) capacitor connected to both the BEOL and FEOL region, where the MIM capacitor connects directly to a via-buried-power-rail (VBPR) that in turn directly connects to the BPDN. In various embodiments, the region of the semiconductor device including the MIM capacitor is distinct from a region of the semiconductor device including one or more transistor devices, the MIM capacitor is located in a dummy-gate region of the semiconductor device, and the dummy gate region does not include a dummy gate or dummy gates (e.g. due to process removal associated with making the semiconductor device)., In one or more embodiments of the present disclosure, the inclusion of the MIMC, as described, mitigates the impact of transient currents, while storing charge associated therewith, and utilizing said charge to power FEOL components in the event of a power outage.

According to yet another embodiment of the present disclosure, a method for manufacturing a semiconductor device is provided. The method includes: providing a substrate, forming one or more nanosheet stacks on the substrate, the one or more nanosheet stacks including at least one sacrificial layer and at least one semiconductor layer, forming a plurality of dummy gates over the substrate, where a portion of the plurality of dummy gates form one or more dummy gate regions, forming a plurality of spacers in contact with one or more sidewalls of the plurality of dummy gates, removing the plurality of dummy gates and the plurality of spacers, depositing a first metal layer and a dielectric layer in one or more recesses associated with the plurality of removed dummy gates, after depositing the first metal layer and the dielectric layer, deposing a second metal layer over the dielectric layer in the one or more recesses, and forming i) a plurality of middle-of-the-line and back-end-of-the line (BEOL) contacts in contact with at least one of the first metal layer and the second metal layer and ii) one or more via for backside power rails (VBPRs) in contact with at least one of the first metal layer and the second metal layer. In various embodiments, the method can further include: forming a back-side power rail (BSPR) that includes one or more portions, where a portion of the BSPR contacts at least one of the one or more VPBRs, depositing a dielectric liner layer over the dielectric layer of the MIM capacitor, forming one or more shallow-trench isolation (STI) regions in relation to substrate, where the one or more shallow-trench isolation regions are each associated with at least one of the portion of the plurality of dummy gates of the one or more dummy gate regions, annealing the dielectric liner layer prior to depositing the second metal layer, depositing a capping layer over the first metal layer prior to depositing the second metal layer, removing the capping layer prior to annealing the dielectric layer, forming a gate region for the semiconductor device, where the second metal layer of the MIM capacitor and at least one metallic component of the gate region are formed during a same deposition process; and annealing at least one gate region layer or gate region portion, where the annealing of the gate region layer or gate portion and the annealing of the dielectric liner layer of the MIM capacitor is during a same annealing process. In one or more embodiments of the present disclosure, the method can further include: forming a S/D region for the semiconductor device, and forming a S/D VBPR in contact with at least one epitaxial layer of the S/D region, where the S/D VBPR is in contact with at least one epitaxial layer of the S/D region and at least one portion of the BSPR contacts the S/D VPBR, where the at least one portion of the BSPR contacting the S/D VBPR and the at least one of the BSPR contacting the one or more VBPRs in contact with the MIM capacitor VPBR are disjointed. In one or more embodiments of the present disclosure, the formation of a semiconductor device with a MIMC, as described, mitigates the impact of transient currents, while storing charge associated therewith, and utilizing said charge to power FEOL components in the event of a power outage, where the formation of the MIMC, as described, makes for a more efficient formation of an overall device, while also allowing for additional processing techniques, e.g. reactive ion etching of certain layers (e.g. high-k layers) early in the overall formation of the semiconductor device.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1D depict a top-down reference view, along with cross-sectional views of a semiconductor structure along the lines X1, X2, and Y of the reference view after an initial set of processing operations according to one or more embodiments of the present disclosure;

FIGS. 2A-2C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more dummy gate regions and associated elements and layers in relation therewith;

FIG. 3A-3C depict cross-sectional views of a semiconductor structure along the lines X1, X2, and Y of the reference view according to one or more embodiments of the present disclosure and pursuant to one or more processing operations according to one or more embodiments of the present disclosure, including removal of one or more sacrificial layers associated with the initial set of processing operations;

FIGS. 4A-4C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more sidewall spacers and dielectric layers;

FIGS. 5A-5C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more source drain regions and one or more inter-dielectric layers;

FIGS. 6A-6C depict cross-sectional views of a semiconductor structure along the lines X1, X2, and Y of the reference view according to one or more embodiments of the present disclosure and pursuant to one or more processing operations according to one or more embodiments of the present disclosure, including removal of one or more dummy gates associated with a dummy gate region and formation of one or more organic planarization layers;

FIGS. 7A-7C depict cross-sectional views of a semiconductor structure along the lines X1, X2, and Y of the reference view according to one or more embodiments of the present disclosure and pursuant to one or more processing operations according to one or more embodiments of the present disclosure, including removal of one or more sidewall spacers associated with a dummy gate region;

FIGS. 8A-8C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more capacitor layers and a capping layer;

FIGS. 9A-9C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more organic planarization layers in relation to a dummy gate region and chamfering of one or more capacitor layers and a capping layer at non-dummy gate region;

FIGS. 10A-10C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more openings for metallic layer or component formation;

FIGS. 11A-11C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more dielectric liners;

FIG. 12A-12C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more gate structures in relation to one or more nanostacks;

FIG. 13A-13C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more metal interconnect layers and carrier wafer bonding;

FIG. 14A-14C depict cross-sectional views of a semiconductor structure along the lines X1, X2, and Y of the reference view according to one or more embodiments of the present disclosure and pursuant to one or more processing operations according to one or more embodiments of the present disclosure, including one or more wafer flip operations in relation to the overall structure and removal of all or a portion of a substrate associated therewith;

FIG. 15A-15C depict cross-sectional views of a semiconductor structure along the lines X1, X2, and Y of the reference view according to one or more embodiments of the present disclosure and pursuant to one or more processing operations according to one or more embodiments of the present disclosure, including removal of one or more etch stop layers and removal of all or a portion of a substrate associated therewith;

FIG. 16A-16C depict cross-sectional views of a semiconductor structure along the lines X1, X2, and Y of the reference view according to one or more embodiments of the present disclosure and pursuant to one or more processing operations according to one or more embodiments of the present disclosure, including formation of one or more inter-layer dielectric layers and one or more power rails;

FIG. 17A-17C depict cross-sectional views of a semiconductor structure along the lines X1, X2, and Y of the reference view according to one or more embodiments of the present disclosure and pursuant to one or more processing operations according to one or more embodiments of the present disclosure, including formation or provision of a backside power distribution network; and

FIG. 18 depicts a semiconductor device according to one or more embodiments of the present disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “connected,” “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

It is understood in advance that although example embodiments of the present disclosure are described in connection with a particular transistor architecture, embodiments of the present disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that can be relevant to aspects of the present disclosure. For example, there are a few candidates for scaling nonplanar transistors beyond the 4 nm node, but each is currently limited due to various factors; one candidate is the nanosheet transistor architecture, which offers advantages in relation to other structures and solutions, including an ability to maintain DC performance. Many semiconductor structures, including those employing nanosheet structures suffer from several drawbacks, including positioning the MIM capacitor in the far BEOL towards the packaging level of a semiconductor device.

Turning now to an overview of aspects of the present disclosure, one or more embodiments of the present disclosure, provide for enhanced co-integration between the BEOL and FEOL of a semiconductor device by utilizing one or more MIM capacitors. Specifically, pursuant to one or more embodiments of the present disclosure, one or more MIM capacitors are cointegrated between the FEOL and BEOL of a semiconductor device, e.g., one employing a nano-sheet structure. The cointegrated MIM scheme can offer several benefits, including i) the ability to store transient charge from one or more power rails or portions of one or more power rails to charge FEOL elements or devices, e.g., transistor(s), in the event of a power outage, ii) increasing the efficiency of the process associated with making a semiconductor device, e.g., forming the MIM capacitor or capacitors during the same portions of the process as the formation of a dummy gate region or regions, and iii) the capacity to make certain high-k layer formations more efficiently and permit annealing of certain high-k layers, including those associated with the MIM-capacitor, which enhances device performance without compromising metallic layers, e.g., BEOL interconnect or other metal layers.

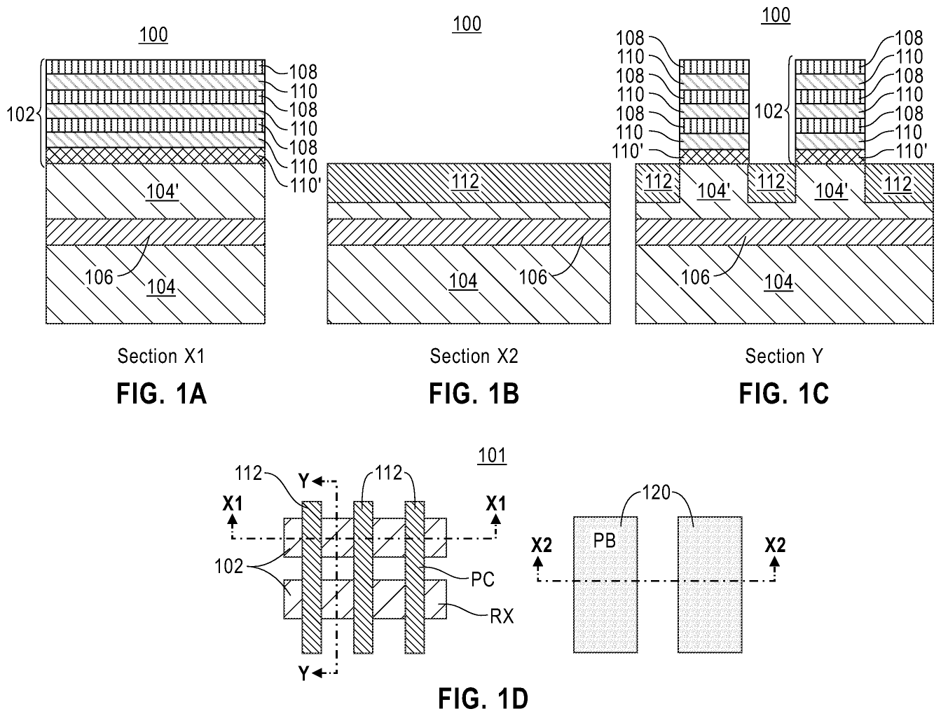

Turning now to a more detailed description of fabrication operations and resulting structures according to aspects of the disclosure, FIGS. 1A-17C depict a semiconductor structure 100 after various fabrication operations in accordance with aspects of the present disclosure.

Fabrication of semiconductor device 100 or semiconductor structure 100 can include multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, semiconductor structure 100 can be fabricated on one or more substrates (e.g., a silicon (Si) substrates, and/or another substrate discussed in more detail below) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

Although the cross-sectional diagrams depicted in FIGS. 1-17 are two-dimensional, it is understood that the diagrams depicted in FIGS. 1-17 represent three-dimensional structures. The top-down reference view 101 shown in FIG. 1D provides a reference point for the various cross-sectional views: X1-view (across gate in channel region), X2-view (along dummy gate or region of shallow-trench isolation region), and Y-view (along gates in source/drain region) shown in FIGS. 1-17. It is noted that, with reference to the drawings, “PC” refers to a gate portion of a device associated with view 101, “PB” refers to either a dummy gate or mask layer over a dummy gate associated with the patterning of a dummy gate region of a device, e.g., in between gates and with respect to a shallow-trench isolation region of a device, and RX refers to an active layer or region, e.g., nanosheet channels and/or source/drain region, of a device. It is to be appreciated that a view, e.g., view “X2,” may be referenced with respect to an element of a structure prior to its inclusion therein or removal thereafter; for example, a dummy gate or hard mask view of a region can still be referred to with respect to a to-be-deposited or added dummy gate or hard mask and/or with respect to an area, region or element that no longer includes the dummy gate or hard mask.

FIGS. 1A-1C depicts cross-sectional views of the semiconductor structure 100 taken along the lines X1, X2 and Y view of the reference view 101 after an initial set of fabrication operations have been applied as part of a method of fabricating a final semiconductor device or semiconductor structure according to one or more embodiments of the present disclosure. In one or more embodiments of the present disclosure, one or more nanosheet stacks 102 are formed over a substrate 104.

The substrate 104 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In one or more embodiments of the present disclosure, the substrate 104 can include a buried oxide layer 106 or etch stop layer 106 in a silicon-on-insulator (SOI) configuration or other suitable configuration. The buried oxide layer or etch stop layer 106 can be made of any suitable material, such as, for example, a silicon oxide or silicon germanium. In one or more embodiments of the present disclosure, the buried oxide layer or etch stop layer 106 is formed to a thickness of about 10-200 nm, although other thicknesses are within the contemplated scope of the present disclosure. In one or more embodiments of the present disclosure, the semiconductor structure 100 can also be formed without the buried oxide layer 106. In that case, an STI (shallow trench isolation) will be formed to isolate device from device. In other embodiments, the buried oxide layer or etch stop layer 106 is included and STI layers or regions are also formed.

In some embodiments of the present disclosure, the substrate 104 can have a substrate portion 104′ that extends above the buried oxide layer or etch stop layer 106, where the substrate can be provided as such and/or any suitable semiconductor process as described herein or otherwise suitable can be used to form the additional substrate portion 104′ over the buried oxide layer or etch stop layer 106 prior to formation of the nanosheet stacks 102. In some embodiments of the present disclosure, the substrate portion 104′ is the same material as the material of the substrate 104, e.g., Si.

In one or more embodiments of the present disclosure, the nanosheet stacks 102 can include one or more semiconductor layers 108 alternating with one or more sacrificial layers 110. In one or more embodiments of the present disclosure, the one or more semiconductor layers 108 and the one or more sacrificial layers 110 are epitaxially grown layers. For ease of discussion, reference is made to operations performed on and to a nanosheet stack having six nanosheets (e.g., the six semiconductor layers 108 shown in FIG. 1C) alternating with six sacrificial layers (e.g., the six sacrificial layers 110), and a selective layer 110′, e.g., to serve as an etch stop layer for the layer 110 immediately above it. It is understood, however, that the nanosheet stacks 102 can include any number of nanosheets alternating with a corresponding number of sacrificial layers. For example, the nanosheet stacks 102 can include two nanosheets, five nanosheets, eight nanosheets, 30 nanosheets (e.g., 3D NAND), or any number of nanosheets, along with a corresponding number of sacrificial layers (i.e., as appropriate to form a nanosheet stack having a bottommost sacrificial layer under a bottommost nanosheet and a sacrificial layer between each pair of adjacent nanosheets).

The one or more semiconductor layers 108 can be made of any suitable material such as, for example, monocrystalline silicon or silicon germanium. In one or more embodiments of the present disclosure, the one or more semiconductor layers 108 are silicon nanosheets. In one or more embodiments of the present disclosure, the one or more semiconductor layers 108 have a thickness of about 4 nm to about 15 nm, for example 10 nm, although other thicknesses are within the contemplated scope of the present disclosure. In one or more embodiments of the present disclosure, the substrate 104 and the one or more semiconductor layers 108 can be made of a same semiconductor material. In other embodiments of the present disclosure, the substrate 104 can be made of a first semiconductor material, and the one or more semiconductor layers 108 can be made of a second semiconductor material.

The one or more sacrificial layers 110 can be silicon or silicon germanium layers, depending on the material of the one or more semiconductor layers 108 to meet etch selectivity requirements. For example, in embodiments where the one or more semiconductor layers 108 are silicon nanosheets, the one or more sacrificial layers 110 can be silicon germanium layers. In embodiments where the one or more semiconductor layers 108 are silicon germanium nanosheets, the one or more sacrificial layers 110 can be silicon germanium layers having a germanium concentration that is greater than the germanium concentration in the one or more semiconductor layers 108. For example, if the one or more semiconductor layers 108 are silicon germanium having a germanium concentration of 5 percent (sometimes referred to as SiGe5), the one or more sacrificial layers 110 can be silicon germanium layers having a germanium concentration of about 25 (SiGe25), although other germanium concentrations are within the contemplated scope of the present disclosure. As shown, and pursuant to some embodiments, the substrate 104 is silicon, layer 110 is a silicon germanium layer, e.g., SiGe 30 (a layer with a germanium concentration of 30 percent), and layer 110′ is selected to serve as an etch stop layer, e.g., SiGe 60 (a layer with a silicon germanium concentration of 60 percent), although other concentrations are within the contemplated scope of the present disclosure.

In one or more embodiments of the present disclosure, the one or more sacrificial layers 110 have a thickness of about 8 nm to about 15 nm, for example 10 nm, although other thicknesses are within the contemplated scope of the present disclosure.

In some embodiments of the present disclosure, portions of the nanosheet stacks 102 can be removed (exposing a surface of the buried oxide or etch stop layer 106) to define the nanosheet stack width. In one or more embodiments of the present disclosure, the width of the nanosheet stacks 102 is about 10-100 nm, although other widths are within the contemplated scope of the disclosure.

As shown in the cross-sectional views Y and X2, one or more shallow trench isolation regions 112 (also referred to as an STI region or STI layer) can be formed adjacent to the nanosheet stacks 102. In one or more embodiments of the present disclosure, a trench is formed by removing portions of the nanosheet stacks 102 and an exposed surface of the substrate 104 is recessed. The trench can then be filled with dielectric material, such as, a low-k dielectric, a nitride, silicon nitride, silicon oxide, SiON, SiC, SiOCN, or SiBCN. The one or more shallow trench isolation regions 112 can provide electrical isolation between the nanosheet stacks 102 and other adjacent devices (such as other nanosheet stacks, or any other active device) on the substrate 104.

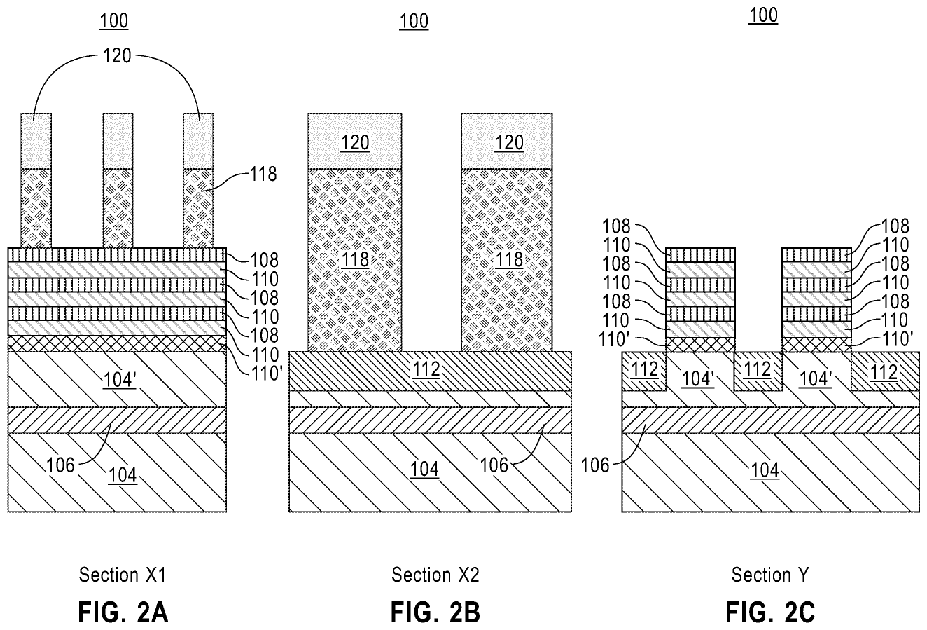

FIGS. 2A-2C depict cross-sectional views of the semiconductor structure 100 taken along the lines X1, X2 and Y of the reference view 101 after one or more processing operations according to one or more embodiments of the present disclosure.

In one or more embodiments of the present disclosure, one or more dummy gates 118 (sometimes referred to as sacrificial layers or dummy layers) are formed over the nanosheet stacks 102. The portion of a nanosheet stack over which a gate is formed is referred to as a channel region. The one or more dummy gates 118 can be made of any suitable material, such as, for example, amorphous silicon or polysilicon. Any known method for patterning a sacrificial gate can be used, such as, for example, a wet etch, a dry etch, or a combination of sequential wet and/or dry etches. In some embodiments of the present disclosure, as shown with reference to view X2, one or more dummy gates 118 are over the one or more shallow-trench isolation regions 112 of the substrate 104 (or substrate portion 104′), and pursuant to one or more embodiments of the present disclosure, this area or areas is referred to as a dummy gate region or regions, even after the one or more dummy gates 118 (and/or any hard masks associated therewith) are removed therefrom.

In one or more embodiments of the present disclosure, a hard mask 120 is formed on the dummy gates 118. In one or more embodiments of the present disclosure, the dummy gates 118 are formed by patterning the hard mask 120 and using a wet or dry etch process to selectively remove portions of the dummy gates 118, which are not covered by the pattered hard mask 120.

The hard mask 120 can be made of any suitable material, such as, for example, a silicon nitride. In one or more embodiments of the present disclosure, a second hard mask (not depicted) is formed on the hard mask 120 to form a bilayer hard mask. In some embodiments, the second hard mask includes an oxide, such as, for example, silicon dioxide.

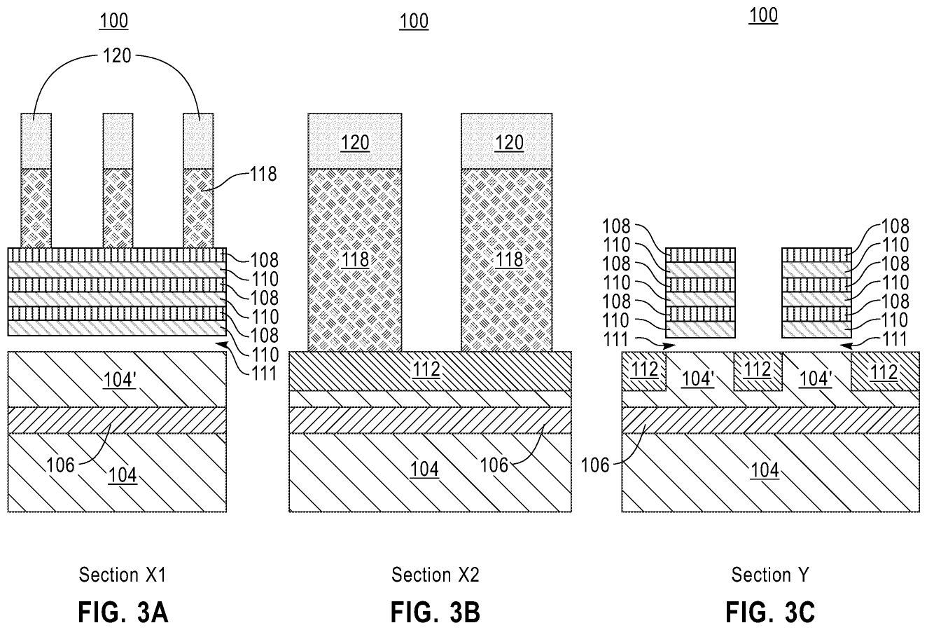

FIGS. 3A-3C depict cross-sectional views of the semiconductor structure 100 taken along the lines X1, X2 and Y of the reference view 101 after one or more processing operations according to one or more embodiments of the present disclosure.

As shown, and pursuant to one or more embodiments of the present disclosure, layer 110′ is selectively removed to form opening 111 using any suitable removal process. In one or more embodiments, an isotropic selective etch process can be used to selectively remove layer 110′, e.g., a SiGe60 layer, to other surrounding materials, e.g., SiGe30 (the material of layer 110) and the substrate 104 (or substrate portion 104′).

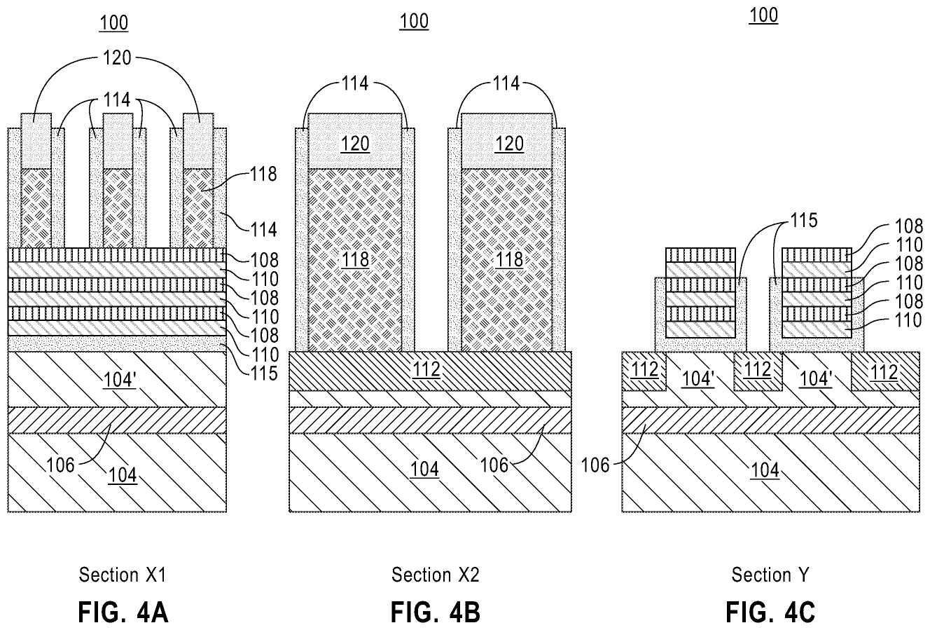

FIGS. 4A-4C depict cross-sectional views of the semiconductor structure 100 taken along the lines X1, X2 and Y of the reference view 101 after one or more processing operations according to one or more embodiments of the present disclosure. In one or more embodiments of the present disclosure, one or more sacrificial spacers 114 are formed on sidewalls of the nanosheet stacks 102 and on sidewalls of the one or more dummy gates 118, and in one or more embodiments, in contact with the hard mask 120. In one or more embodiments of the present disclosure, the one or more sacrificial spacers 114 are formed using a chemical vapor deposition (CVD), plasma-enhanced CVD (PECVD), ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), atomic layer deposition (ALD), physical vapor deposition (PVD), chemical solution deposition, molecular beam epitaxy (MBE), or other like process in combination with a wet or dry etch process. For example, sacrificial spacer material can be conformally deposited over the semiconductor structure 100 and selectively removed using a RIE to form the sacrificial spacer 114. The sacrificial spacer material can include, for example, amorphous silicon germanium (a-SiGe), although other sacrificial materials are within the contemplated scope of the present disclosure. In one or more embodiments of the present disclosure, the sacrificial spacer 114 has a thickness of about 5 nm to about 15 nm, for example 6 nm, although other thicknesses are within the contemplated scope of the present disclosure.

In one or more embodiments, the one or more sacrificial spacers 114 can be made of any suitable material, such as, for example, a low-k dielectric, a nitride, silicon nitride, silicon oxide, SiON, SiC, SiOCN, or SiBCN. In one or more embodiments of the present disclosure, the spacer 114 include silicon nitride. In one or more embodiments, and as shown, one or more bottom dielectric isolation layers (BDI) 115 can be formed as part of the one or more process steps associated with forming the one or more sacrificial spacers 114. In one or more embodiments of the present disclosure, both the one or more spacers 114 and the one or more BDIs 115 are a low-k dielectric, and in one or more embodiments, the one or more spacers 114 and the one or more BDIs 115 are the same material, e.g., thus permitting a same process, step or steps associated with forming the one or more spacers 114 to form the one or more BDIs 115, and where the one or more BDIs 115 and one or more spacers 114 can be made of any suitable material, such as, for example, a low-k dielectric, a nitride, silicon nitride, silicon oxide, SiON, SiC, SiOCN, or SiBCN.

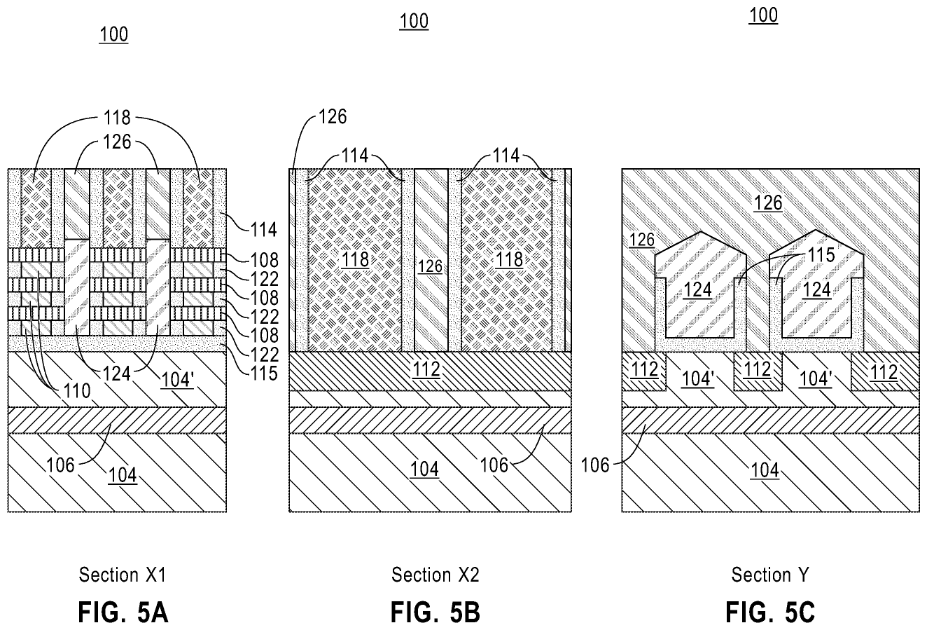

FIGS. 5A-5C depict cross-sectional views of the semiconductor structure 100 taken along the lines X1, X2 and Y of the reference view 101 after one or more processing operations according to one or more embodiments of the present disclosure. In some embodiments of the present disclosure, portions of the nanosheet stacks 102 can be removed (sometimes referred to as a stack recess) to expose a surface of the BDI 115. The nanosheet stacks 102 can be patterned using, for example, a wet etch, a dry etch, or a combination of wet and/or dry etches. In some embodiments of the present disclosure, the nanosheet stacks 102 is patterned using a RIE. The nanosheet stacks 102 can be patterned selective to the one or more spacers 114.

In some embodiments of the present disclosure, the one or more sacrificial layers 110 can be recessed and one or more inner spacers 122 can be formed on the recessed sidewalls of the one or more sacrificial layers 110. For example, sidewalls of the one or more sacrificial layers 110 can be recessed to form cavities (not shown) in the nanosheet stacks 102. The one or more inner spacers 122 can be formed on recessed sidewalls of the one or more sacrificial layers 110 by filling these cavities with dielectric material. In some embodiments of the present disclosure, portions of the one or more inner spacers 122 that extend beyond sidewalls of the nanosheet stack 102 are removed, using, for example, an isotropic etching process. In this manner, sidewalls of the one or more inner spacers 122 are coplanar to sidewalls of the one or more semiconductor layers 108. In some embodiments of the present disclosure, the one or more inner spacers 122 are formed using a CVD, PECVD, ALD, PVD, chemical solution deposition, or other like processes in combination with a wet or dry etch process. The one or more inner spacers 302 can be made of any suitable material, such as, for example, a low-k dielectric, a nitride, silicon nitride, silicon dioxide, SiON, SiC, SiOCN, or SiBCN.

In some embodiments of the present disclosure, one or more source and drain regions 124 are formed on exposed sidewalls of the one or more semiconductor layers 108. The one or more source and drain regions 124 can be epitaxially grown using, for example, vapor-phase epitaxy (VPE), molecular beam epitaxy (MBE), liquid-phase epitaxy (LPE), or other suitable processes. The one or more source and drain regions 124 can be semiconductor materials epitaxially grown from gaseous or liquid precursors.

In some embodiments of the present disclosure, the gas source for the epitaxial deposition of semiconductor material includes a silicon including gas source, a germanium including gas source, or a combination thereof. For example, a Si layer can be epitaxially deposited (or grown) from a silicon gas source that can be any one of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and/or combinations thereof. A germanium layer can be epitaxially deposited from a germanium gas source that is selected from the group consisting of germane, digermane, halogermane, dichlorogermane, trichlorogermane, tetrachlorogermane and combinations thereof. A silicon germanium alloy layer can be epitaxially formed utilizing a combination of such gas sources. Carrier gases like hydrogen, nitrogen, helium and argon can be used. In some embodiments of the present disclosure, the epitaxial semiconductor materials include carbon doped silicon (Si:C). This Si:C layer can be grown in the same chamber used for other epitaxy steps or in a dedicated Si:C epitaxy chamber. The Si:C can include carbon in the range of about 0.2 percent to about 3.0 percent.

In some embodiments of the present disclosure, epitaxially grown silicon and silicon germanium can be doped by adding n-type dopants (e.g., P or As) or p-type dopants (e.g., Ga, B, BF2, or Al). In some embodiments of the present disclosure, the source and drain regions 304 can be epitaxially formed and doped by a variety of methods, such as, for example, in-situ doped epitaxy (doped during deposition), doped following the epitaxy, or by implantation and plasma doping. The dopant concentration in the doped regions can range from 1×1019 cm−3 to 2×1021 cm−3, or between 1×1020 cm−3 and 1×1021 cm−3.

In some embodiments of the present disclosure, the one or more source and drain regions 124 are made of silicon or silicon germanium. The one or more source and drain regions 124 can be made of silicon germanium doped with boron to a boron concentration of about 1 to about 15 percent, for example, 2 percent, although other boron concentrations are within the contemplated scope of the present disclosure.

In some embodiments of the present disclosure, one or more isolation dielectric layers or inter-layer dielectric layers (ILD) 126 can be formed over the source and drain regions 124. The one or more ILD layers 126 can be made of any suitable dielectric material, such as, for example, oxides, a low-k dielectric, nitrides, silicon nitride, silicon oxide, SiON, SiC, SiOCN, and SiBCN. In some embodiments of the present disclosure, the one or more ILD layers 126 can be deposited over the semiconductor structure 100 and the semiconductor structure 100 is then suitably planarized, e.g., to a topmost surface of the dummy gates 118 using any suitable process, for example chemical-mechanical planarization (CMP).

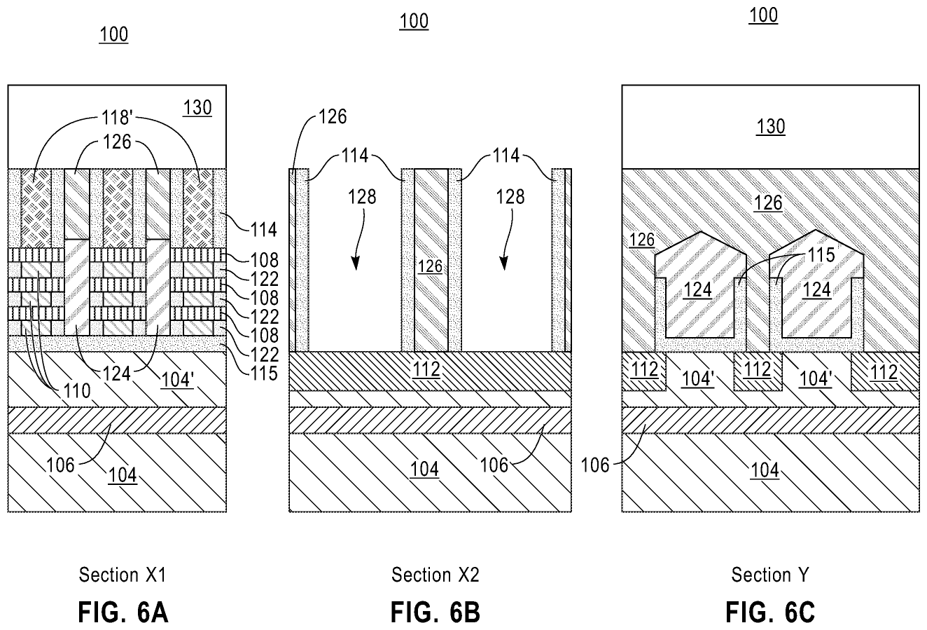

FIGS. 6A-6C depict cross-sectional views of the semiconductor structure 100 taken along the lines X1, X2 and Y of the reference view 101 after one or more processing operations according to one or more embodiments of the present disclosure. In some embodiments of the present disclosure, the one or more dummy gates 118 are removed, where any suitable method for removing a dummy gate can be used, such as, for example, a wet etch, a dry etch, or a combination of sequential wet and/or dry etches. In one example, the one or more dummy gates 118 are removed using ammonia wet chemistry (e.g., hot chemical etching).

In some embodiments of the present disclosure, as shown, an organic planarization layer (OPL) 130 is coated on the structure 100 used to pattern the one or more dummy gates 118. The OPL 130 can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the OPL 130 can include any organic polymer and a photo-active compound having a molecular structure that can attach to the molecular structure of the organic polymer. In some embodiments, the OPL 130 material is selected to be compatible an overlying antireflective coating (not shown) and/or an overlying photoresist (not shown). In some embodiments, the OPL 130 can be applied using spin coating technology, although other techniques are within the contemplated scope of the present disclosure. In one or more embodiments of the present disclosure, the OPL 130 can then be patterned to form one or more openings, recesses (or trenches) 128. The OPL 130 can be patterned using, for example, photolithography followed by a dry etch, or a combination of sequential dry and/or wet etches.

As shown, and pursuant to one or more embodiments of the present disclosure, after the processes and techniques discussed with respect to FIGS. 5A-5C and FIGS. 6A-6C take place, dummy gates 118′ remain in relation to nanosheet stacks 102.

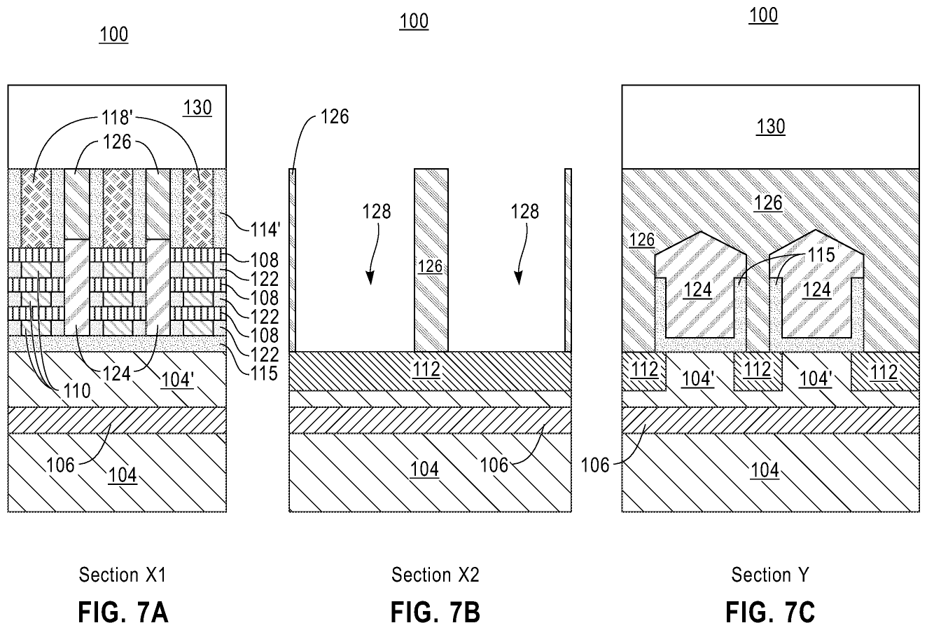

FIGS. 7A-7C depict cross-sectional views of the semiconductor structure 100 taken along the lines X1, X2 and Y of the reference view 101 after one or more processing operations according to one or more embodiments of the present disclosure. As shown and pursuant to one or more embodiments of the present disclosure, the one or more sidewall spacers 114 associated with openings (sometimes referred to herein as “recesses” or “trenches”) 128 are removed using any suitable processes or technique, including dry or wet etching, and in one or more embodiments, the removal can be selective to both the one or more STI regions 112 and the ILD layer 126 material. In one or more embodiments of the present disclosure, as shown, the one or more sidewall spacers 114′ associated with the nanosheet stacks 102 remain intact.

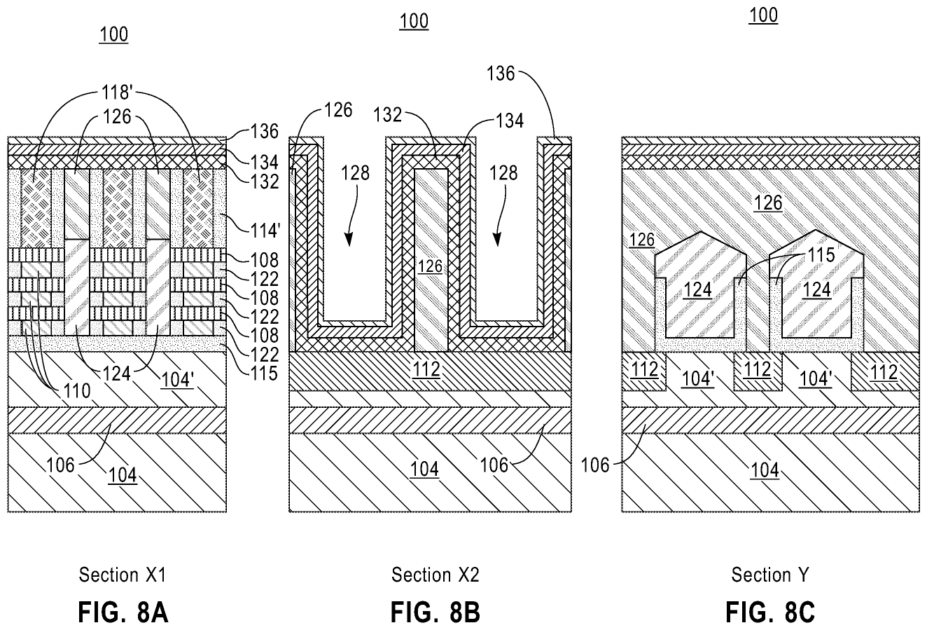

FIGS. 8A-8C depict cross-sectional views of the semiconductor structure 100 taken along the lines X1, X2 and Y of the reference view 101 after one or more processing operations according to one or more embodiments of the present disclosure. In some embodiments of the present disclosure, as shown, the OPL 130 can be removed using, for example, ashing or any other suitable removal technique. As depicted in FIGS. 8A-8C, one or more first conducting layers 132 for one or more capacitors is deposited in relation to the one or more STI regions 112. In one or more embodiments of the present disclosure, the one or more first conducting layers 132 can include any suitable metal or material, including but not limited to: polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tungsten silicide, tungsten nitride, ruthenium oxide, cobalt silicide, nickel silicide), carbon nanotube, conductive carbon, or any suitable combination of these materials. The conductive material may further include dopants that are incorporated during or after deposition. The one or more first conductive layers 132 can be formed using any suitable deposition process, including using CVD. In one or more embodiments of the present disclosure, the one or more conductive layers 132 can include or be entirely composed of a metal material, including those described herein, and as such, the first conductive layer 132 or first conduct layers 132 can be a metal layer 132 or metal layers 132.

In one or more embodiments, a first dielectric layer 134 (e.g., one or more dielectric layers 134) associated with one or more MIM capacitors is deposited over the one or more first conductive layer 132s, where the dielectric layer can be a high-k dielectric layer, such as a layer made of hafnium oxide, and the dielectric layer 134 can be formed using CVD. However, the present disclosure is not limited to the use of hafnium oxide, and the first dielectric layer can be composed of other materials including but not limited to: silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material can further include dopants such as lanthanum, aluminum, etc.

Furthermore, although CVD is described for forming the first dielectric layer 134, the first dielectric layer 134 can be formed by any suitable process such as, for example: thermal oxidation, chemical oxidation, thermal nitridation, atomic layer deposition (ALD), molecular layer deposition (MLD), chemical vapor deposition (CVD), low-pressure chemical vapor deposition (LPCVD), plasma enhanced chemical vapor deposition (PECVD), high density plasma chemical vapor deposition (HDPCVD), sub-atmospheric chemical vapor deposition (SACVD), rapid thermal chemical vapor deposition (RTCVD), in-situ radical assisted deposition, high temperature oxide deposition (HTO), low temperature oxide deposition (LTO), ozone/TEOS deposition, limited reaction processing CVD (LRPCVD), ultrahigh vacuum chemical vapor deposition (UHVCVD), metalorganic chemical vapor deposition (MOCVD), molecular beam epitaxy (MBE), physical vapor deposition, sputtering, plating, evaporation, spin-on-coating, ion beam deposition, electron beam deposition, laser assisted deposition, chemical solution deposition, or any combination of the aforementioned.

In one or more embodiments of the present disclosure, a capping layer 136 is formed over the semiconductor structure 100, e.g., over the first dielectric layer 134. In one or more embodiments of the present disclosure, the capping layer 136 can be conformally deposited over the semiconductor structure 100 using, for example, ALD, although other conformal deposition processes are within the contemplated scope of the present disclosure. The capping layer 136 can be made of any suitable material, such as, for example, a low-k dielectric or an oxide (e.g., SiO2).

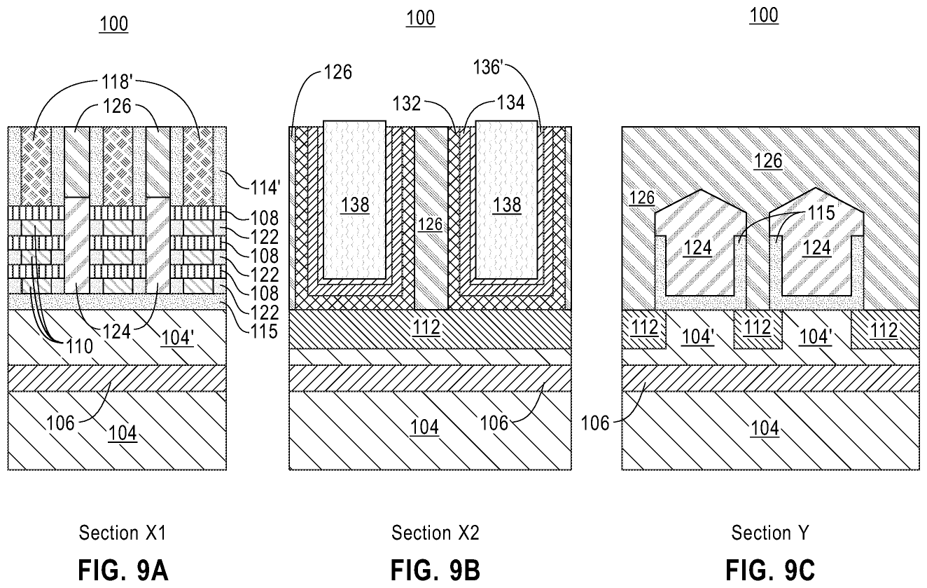

FIGS. 9A-9C depict cross-sectional views of the semiconductor structure 100 taken along the lines X1, X2 and Y of the reference view 101 after one or more processing operations according to one or more embodiments of the present disclosure. As shown, and pursuant to some embodiments of the present disclosure, a chamfering process for MIM capacitor's first conducting layers 132, first dielectric layer 134 and capping layer 136 can be applied. The MIM capacitor layer chamfering process can result in formation of a (second) organic planarization layer (OPL) material 138 in the one or more openings or recesses 128, and removal of all capping material of capping layer 136, except for capping material (e.g., cap inner liner) 136′ over the dielectric layer 134.

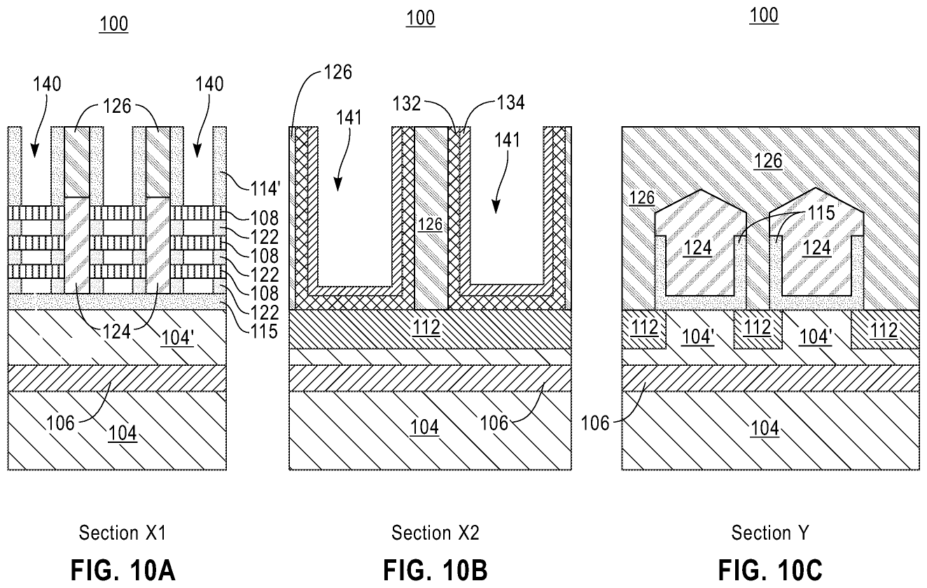

FIGS. 10A-10C depict cross-sectional views of the semiconductor structure 100 taken along the lines X1, X2 and Y of the reference view 101 after one or more processing operations according to one or more embodiments of the present disclosure. In one or more embodiments of the present disclosure, the one or more sacrificial layers 110, and the one or more dummy gates 118′ can be removed to form one or more cavities or openings 140 that releases the one or more semiconductor layers 108 (once released, the semiconductor layers 108 are often referred to as nanosheets). In one or more embodiments of the present disclosure, the one or more dummy gate 118′ can be removed by etch process, e.g., wet ammonia etch, and the one or more sacrificial layers 110 can be removed selective to the one or more semiconductor layers 108 using any suitable technique to do so. For example, when the one or more semiconductor layers 108 are formed of silicon, the one or more sacrificial layers 110 are formed of SiGe, carboxylic acid/nitric acid/HF chemistry, citric acid/nitric acid/HF, and vapor phased HCl, for example, can be utilized to remove SiGe selective to silicon. In another example, when the one or more semiconductor layers 108 are formed of SiGe, the one or more sacrificial layers 110 are formed of silicon, aqueous hydroxide chemistry, including ammonium hydroxide and potassium hydroxide, for example, can be utilized to remove silicon selective to SiGe.

In one or more embodiments of the present disclosure, the OPL material 138 used to fill recesses 128 can be removed using any suitable technique, e.g. ashing, forming openings or recesses 141 prior to the one or more sacrificial layers 110 and the one or more dummy gate 118 removal, and a pre-clean process after the one or more sacrificial layers 110, and the one or more dummy gate sacrificial spacers 118 removal can be performed in an attempt to remove all foreign materials from within respect to the openings or recesses 141, including the cap liner layer 136′. In one or more embodiments, the pre-clean can be performed using any suitable technique as described herein or otherwise suitable.

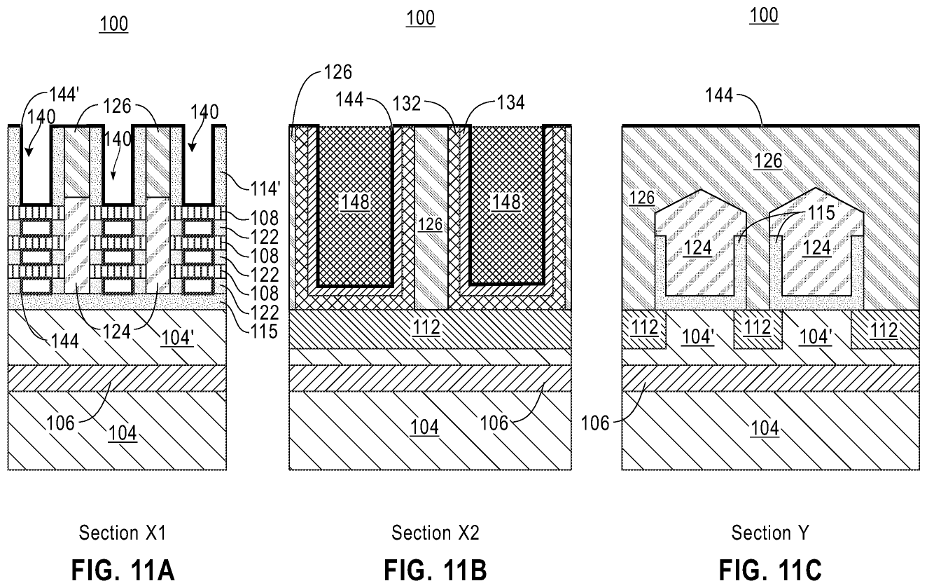

FIGS. 11A-11C depict cross-sectional views of the semiconductor structure 100 taken along the lines X1, X2 and Y of the reference view 101 after one or more processing operations according to one or more embodiments of the present disclosure. In one or more embodiments of the present disclosure, a high-k (e.g., a k value greater than 10) dielectric liner 144, such as hafnium oxide, having a thickness that is less than the thickness of the one or more dielectric layers 134. In one or more embodiments of the present disclosure, the dielectric liner 144 is between 1 nm-2 nm in thickness. In one or more embodiments, the dielectric liner 144 can be deposited by performing conformal deposition such an ALD process. In one or more embodiments of the present disclosure, the deposition of the dielectric material associated with dielectric liner 144 is such that dielectric portions or liners 144′ are along some or all of the boundaries of openings 140 (as shown), including portions of one or more gate region layers or gate region portions as shown. In one or more embodiments, an anneal process may be performed to increase the reliability of the high-k gate insulation or dielectric layer 134 with the liner 144 deposited thereover (e.g. where in one or more embodiments, the combination of the two after an anneal results in a superior functioning dielectric layer associated with a MIM capacitor) and portions or liners 144′. The parameters of such an anneal process are well known to those skilled in the art, e.g., depending on the material selected for the one or more dielectric layers 134, liner 144 and liners or portions of liners 144′, etc.

In one or more embodiments, as discussed above, annealing the dielectric liner 144 and liners or portions 144′ offers an advantage over other techniques in that many metallic components associated with structure 100, including layers discussed below with respect to a MIM-capacitor, transistor and/or FEOL elements, middle of the line elements, and BEOL elements, are yet to be deposited, and the reliability anneal can improve the functioning of a final device, without damaging other components, e.g., metallic components. Moreover, the deposition of liner 144 and/or liners or portions 144′ can be done pursuant to concurrent or sequential operations, prior to deposition of other layers, which makes for a more efficient manufacturing process.

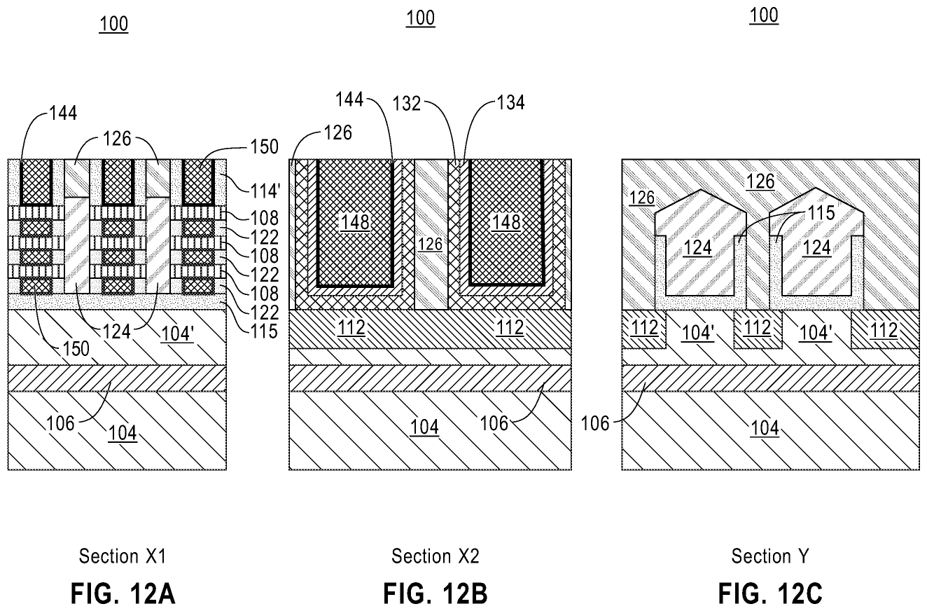

FIGS. 12A-12C depict cross-sectional views of the semiconductor structure 100 taken along the lines X1, X2 and Y of the reference view 101 after one or more processing operations according to one or more embodiments of the present disclosure. In some embodiments of the present disclosure, a second conducting layer 148, e.g., one or more second conducting layers 148 of a MIM capacitor is formed during one or more process steps where one or more gates 150 associated with the nanosheet stacks 102, e.g., FEOL logic components, are also formed. In one or more embodiments, the second conducting layer 148 is a second metallic layer 148 of a MIM capacitor, where the second metallic layer 148 can be any suitable material as described herein.

In one or more embodiments, the one or more gates 150 include one or more work function layers (sometimes referred to as a work function metal stack) are formed in openings 140 using any suitable deposition process described herein or otherwise suitable. In some embodiments of the present disclosure, the one or more gates 150 can include one or more work function layers, can include a bulk gate material (not shown), and in others, they do not include a bulk gate material.

If present, the work function layers can be made of, for example, aluminum, lanthanum oxide, magnesium oxide, strontium titanate, strontium oxide, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layer can serve to modify the work function of the one or more gates 150 and enables tuning of the device threshold voltage. The work function layers can be formed to a thickness of about 0.5 to 6 nm, although other thicknesses are within the contemplated scope of the present disclosure. In some embodiments of the present disclosure, each of the work function layers can be formed to a different thickness. In some embodiments of the present disclosure, the work function layers include a TiN/TiC/TiCAl stack.

In some embodiments, the one or more gates 150 include a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate material can further include dopants that are incorporated during or after deposition.

In some embodiments of the present disclosure, the second conducting layer 148 or the second conducting layers 148 can be deposited composed of: polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tungsten silicide, tungsten nitride, ruthenium oxide, cobalt silicide, nickel silicide), carbon nanotube, conductive carbon, or any suitable combination of these materials. The conductive material may further include dopants that are incorporated during or after deposition. In some embodiments of the present disclosure, the second conducting layer or layers 148 is a second metallic layer or layers 148 that is all or partly metallic, e.g., metallic material as described herein.

In one or more embodiments of the present disclosure, the one or more gates 150 and the second conducting layer or layers 148, e.g., a second metallic layer or layers 148, can be deposited using the same technique, e.g., deposition technique, such as CVD, and in other embodiments different types of deposition can be used for one. In one or more embodiments, the metallic composition of the one or more gates 150 and the second metallic layer 148 can be same. In one or more embodiments, as suitable, sputtering, evaporation or electrochemical plating can be employed to deposit the metal(s) associated with gates 150 and layer 148 in their respective openings.

In one or more embodiments, forming the material, e.g., metallic material, associated with the one or more gates 150 and the second metallic layer 148 during the same or series of same deposition or other formation techniques enhances the efficiency of the overall manufacturing process, which, in one or more embodiments, is exacerbated in light of the annealing benefits outlined with respect to FIGS. 11A-11C.

In one or more embodiments, as shown, the addition of gates 150 completes formation of one or more MIM capacitors.

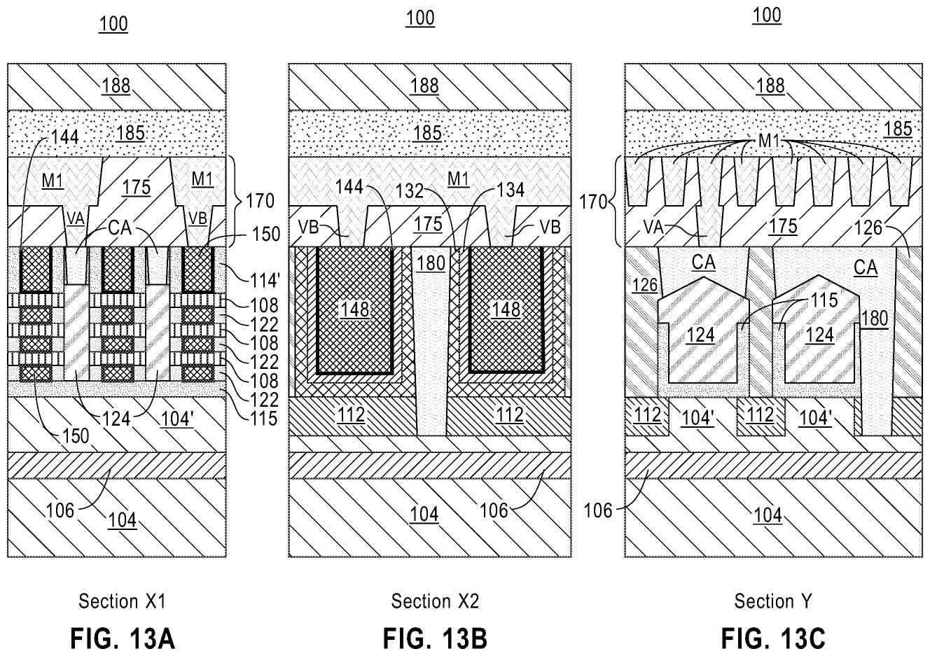

FIGS. 13A-13C depicts cross-sectional views of the semiconductor structure 100 taken along the lines X1, X2 and Y of the reference view 101 after one or more processing operations according to one or more embodiments of the present disclosure. In some or more embodiments of the present disclosure, as shown, FIGS. 13A-13C depict provision or formation of a middle-of-the-line (MOL region) and associated interconnects, provision or formation of a back-end-of-the-line region (BEOL region), and provision and/or bonding of a carrier wafer.

In one or more embodiments of the present disclosure, a MOL region 170 that includes one or more metal contacts M1 (otherwise referred to as electrical interconnects M1 or metal interconnects M1), one or more via contacts VA and VB, and at least one another ILD layer 175 is shown. In one or more embodiments of the present disclosure, gate via contact VB connects a metal gate electrode, e.g., the top or second conduct layer 148 layer as shown to one of the metal contacts M1, where in one or more embodiments, the metal contacts M1 can include an electrical line (or wire) to route electrical connections to and from layer 148 (e.g., one or more gates of the FEOL nanosheet stacks 102). In one or more embodiments, a contact M1 and a via contact VA to connect the common source/drain region 124. The via contacts VA and VB and the electrical interconnects M1 can include metallic fill material including, but not limited to, tungsten (W), cobalt (Co), ruthenium (Ru), copper (Cu), or combinations thereof, as well as thin liner layers (not shown) (e.g., TiN and/or TaN barrier layer and/or seed layer) which are formed prior to depositing the metallic fill material. In one or more embodiments, any suitable technique, including deposition techniques discussed herein, e.g., CVD, can be used to form the metallic contacts and vias of region 170. In one or more embodiments, as suitable, a process such as sputtering, evaporation or electrochemical plating can be employed to form contacts M1, VA, and/or VB.

In one or more embodiments, the source/drain via VA can form a contact area on the epitaxial material associated with the one or more source/drain region 124, e.g. a respective contact area CA in relation to each. In one or more embodiments, the contact area CA can include a shared silicide trench contact, as is understood by one of ordinary skill in the art. In this example embodiment, the source/drain contact area CA (as a shared silicide trench contact) can include a silicide layer disposed between the relevant source/drain layer 124 and the metallic fill material that forms the via VA. The silicide layer is formed by depositing a thin layer of a transition metal such as nickel (Ni), cobalt (Co), titanium (Ti), platinum (Pt), tungsten (W), tantalum (Ta), an alloy such as titanium-aluminum (TiAl) or titanium-nitride (TiN), etc., or any other suitable metallic material, on an exposed surface of the epitaxial source/drain layer 124 (or on an additional thin epitaxial semiconductor layer grown on the source/drain layer 124). A thermal anneal process can be performed at an appropriate temperature to induce a reaction between the epitaxial material and the transition metal layer to form a metal-semiconductor alloy layer (or silicide layer).

In one or more embodiments, another insulating layer or another ILD layer 175 can be formed by any suitable technique as discussed herein and can be composed of any suitable material as described herein. In one or more embodiments, the ILD layer 175 can be patterned to form contact openings which are filled with metallic material to form the MOL contacts M1, VA, and VB, where the patterning can be pursuant to any suitable techniques as discussed herein or otherwise, e.g., a suitable etching technique.

In one or more embodiments, one or more (via for backside power rails) VBPRs 180 are formed (as shown). In one or more embodiments (not shown), one or more patterning techniques, e.g., etching or other suitable techniques, to form openings for creating a VBPR are created in relevant portions of structure 100, including utilizing suitable RIE and/or other techniques to create one or more openings in STI layer 112, ILD layer 126, and substrate 104′, where in one or more embodiments an opening through all layers and/or regions 104′, 112, and 126 can accommodate a VBPR 180. In one or more embodiments, any suitable self-alignment technique can be used with respect to the one or more VBPRs 180.

In one or more embodiments, as shown, at least one VBPR 180 contacts (e.g., directly contacts) at least one conducting layer of a MIM capacitor, e.g., a metal layer 132 forming a bottom or first electrode of a MIM capacitor. In one or more embodiments, the VPBR 180 contacting the metal layer 132 also contacts another ILD layer 175, the STI layer 112, and substrate portion 104′.

In one or more embodiments, as shown, at least one other VBPR 180 contacts the source/drain region 124. In one or more embodiments, the at least one other VBPR contact 180 can be formed as described with respect to the VPBR contact 180 contacting an electrode of a MIM capacitor, e.g., by one or more patterning or removal techniques, e.g., an etch (e.g., RIE), forming openings in relevant layer, such as the substrate portion 104′, STI layer 112, and/or ILD layer 126, followed by a suitable deposition, alignment, or formation technique as discussed herein or otherwise. In one or more embodiments, the VPBR contact 180 in contact with the S/D region 124, e.g., an epitaxial material associated therewith, can form a contact area CA that is of a same type as the contact area CA described with reference to via VA.

In one or more embodiments, any suitable deposition technique, including CVD, can be used to form the VBPRs 180. In one or more embodiments, A process such as sputtering, evaporation or electrochemical plating can be employed to deposit the metal(s) into relevant openings (not shown) to form the VBPRs 180.

In one or more embodiments, a back end of the line (BEOL) layer or region 185 is formed or provided to further facilitate interconnection of the overall semiconductor structure. Any suitable techniques, materials and devices (not shown) for forming a BEOL region or layer 185 can be used, including for example transistors, capacitors, resistors, etc., where one or more BEOL interconnects (not shown) or other devices (not shown) are formed in contact with the one or more contacts M1, and where in one or more embodiments, the BEOL region or layer 185 can complete one or more (or all) of relevant circuits of the structure 100.

In one or more embodiments, a carrier or handle wafer 188 can be bonded to structure 100 by bonding to a suitable portion of BEOL layer 185 using any suitable bonding technique and/or any other techniques to known to one skilled in the art for facilitating a bonding of a carrier wafer 188 to a semiconductor layer or region, e.g., BEOL layer 185, and where the carrier wafer 188 can be any suitable material associated with a carrier wafer or handling wafer.

In one or more embodiments the carrier wafer 188 can be composed of Si or a glass. In one or more embodiments, the bonding to the BEOL layer 185 can be accomplished using fusion bonding (for example silicon oxide to silicon oxide) or by means of intermediate-layer bonding (for example using adhesives).

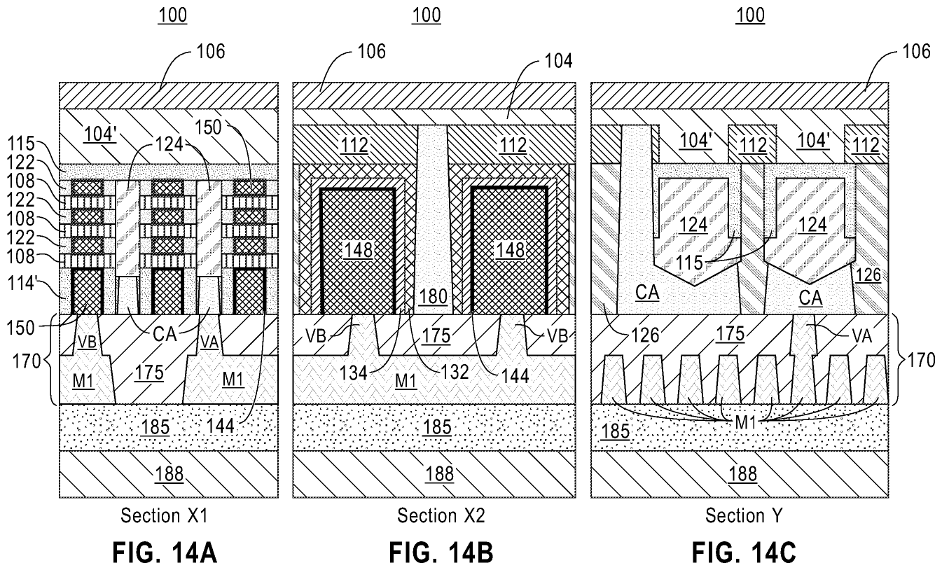

FIGS. 14A-14C depict cross-sectional views of the semiconductor structure 100 taken along the lines X1, X2 and Y of the reference view 101 after one or more processing operations according to one or more embodiments of the present disclosure. In one or more embodiments, a wafer flip is performed on structure 100, e.g., using wafer 188 or any other suitable technique, the semiconductor structure 100 is turned upside down. In one or more embodiments, the substrate 104 is removed using any suitable removal technique, e.g., grinding, chemical mechanical planarization (CMP) and/or wet etch, as described herein or otherwise suitable, where the layer 106, e.g., an insulator or buried oxide layer 106, can serve as an etch stop layer in relation to substrate portion 104′.

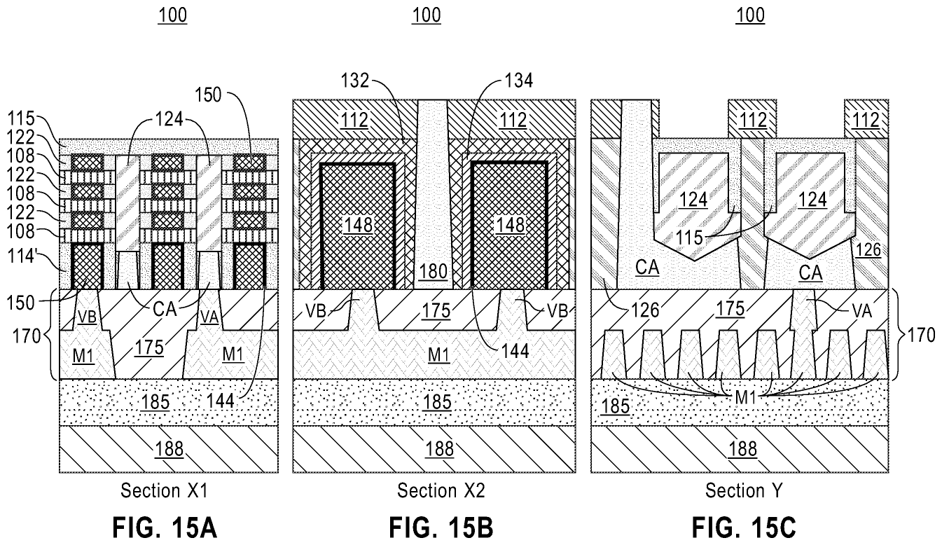

FIGS. 15A-15C depict cross-sectional views of the semiconductor structure 100 taken along the lines X1, X2 and Y of the reference view 101 after one or more processing operations according to one or more embodiments of the present disclosure. In one or more embodiments, substrate portion 104′ and layer 106, e.g., etch stop layer or buried insulator layer 106, are further removed to enable formation or provision of a back-side power-rail (BSPR), additional (third) inter-layer dielectric layer and a backside power distribution network (BSPDN) (as discussed below). In one or more embodiments, the removal of substrate portion 104′ and layer 106′ can be pursuant to any suitable removal technique or techniques, including but not limited to any dry or wet etch.

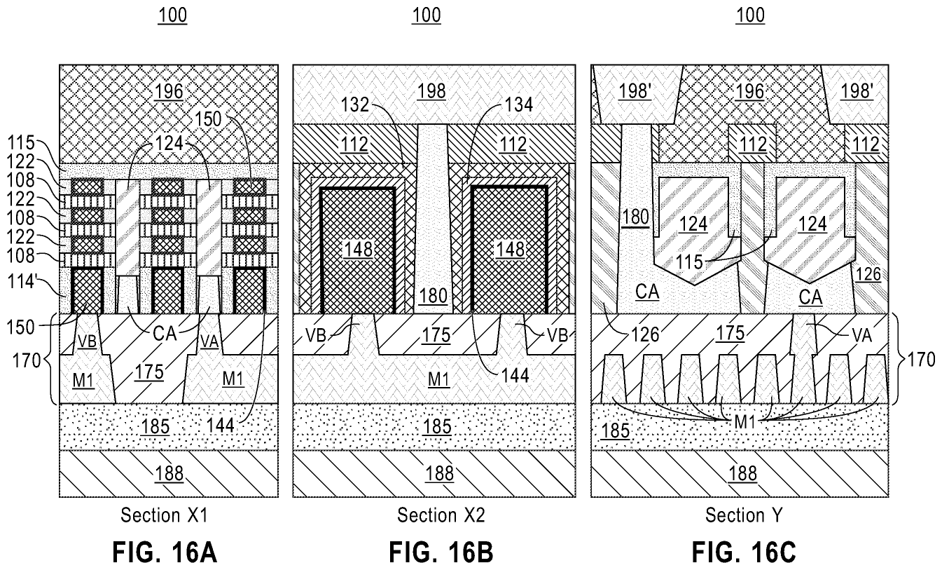

FIGS. 16A-16C depict cross-sectional views of the semiconductor structure 100 taken along the lines X1, X2 and Y of the reference view 101 after one or more processing operations according to one or more embodiments of the present disclosure. In one or more embodiments of the present disclosure, yet another ILD layer or back ILD (BILD) layer 196 (e.g. BILD 196) is deposited over structure 100. Any suitable deposition, e.g., conformal deposition, followed by any other suitable technique, e.g., CMP, can be used to form BILD 196. In one or more embodiments, BILD layer 196 can be formed using one or more techniques associated with ILD layer 126 or ILD layer 175. In one or more embodiments, structure 100 has at least three ILD layers, e.g., first ILD layer 126, second ILD layer 175, and third ILD layer, e.g., BILD 196. In one or more embodiments, any suitable patterning technique, e.g., etch or otherwise, can be used on layer BILD 196 to form one or more openings or holes (not shown). In one or more embodiments, using any suitable technique, e.g., by depositing a conductive metal into openings using CVD or plating (and/or sputtering, evaporation or electrochemical plating), a backside power rail (BSPR) 198 is formed and VSS and/or VDD, i.e., layers, portions, or rails 198′, are also formed. In one or more embodiments, since BSPR 198 and VSS/VDD portions 198′ are made during the same process and or sequence of techniques, the BSPR can be considered a single rail including 198 and portions 198′, even though layer (e.g. of BSPR) 198 and portions 198′ are disjointed. In one or more embodiments, each portion, e.g., 198 and 198′, can be considered a separate rail, with one of 198′ being a VDD rail 198′ and the other 198′ being a ground or VSS rail 198′.

In one or more embodiments, as shown, the VBPR 180 in contact with layer 132 (e.g., the MIM capacitor VBPR) contacts BSPR 198, and the VBPR 180 in contact with the S/D region 124 via contact area CA (e.g., the S/D region VBPR). Accordingly, pursuant to one or more embodiments of the present disclosure, one or more MIM capacitors provide an avenue for minimizing the impact of transient currents in semiconductor structure 100, while also providing a technique for storing charge in the MIM capacitors to power devices inside the structure, e.g., logic devices associated with FEOL functionality (e.g., nanosheet stacks 102), in the event of a power failure internally or otherwise.

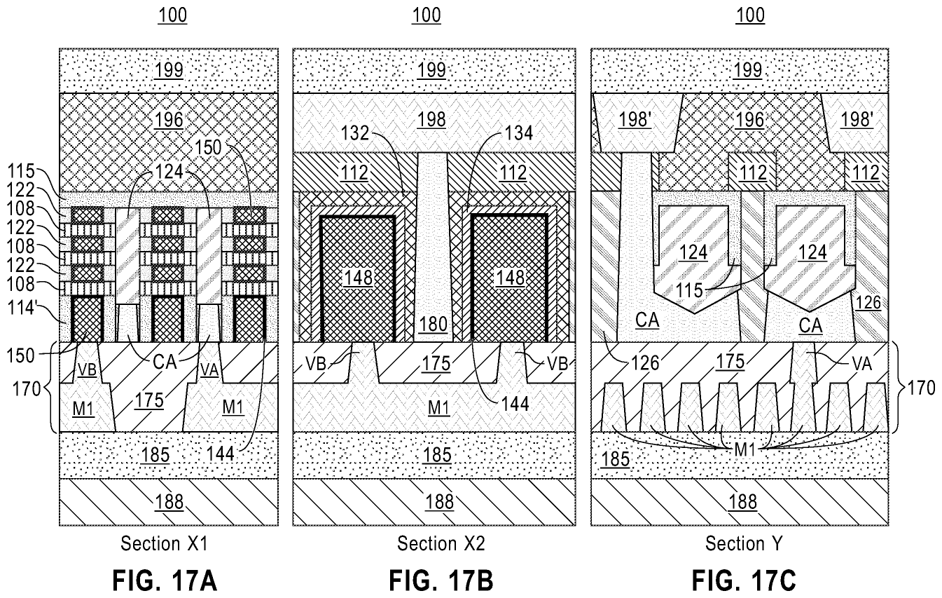

FIGS. 17A-17C depict cross-sectional views of the semiconductor structure 100 taken along the lines X1, X2 and Y of the reference view 101 after one or more processing operations according to one or more embodiments of the present disclosure. In one or more embodiments of the present disclosure a backside power distribution network (BSPDN) 199 is provided over the semiconductor structure 100, and can be in direct contact with BILD 196, BSPR 198, and BSPR 198′. In one or more embodiments, the BSPDN is formed as single network and in other embodiments one or more interoperable and interconnected networks. In one or more embodiments, any suitable technique for forming or providing a BSPDN can be utilized, including one that utilize a series of metal interconnects (not shown) or through-silicon via (TSVS) (not shown) to connect to relevant portions of semiconductor structure 100, including BSPR 198 and BSPR portions 198′, and where the BSPDN 199 can deliver power to semiconductor structure 100 utilizing any suitable power source.

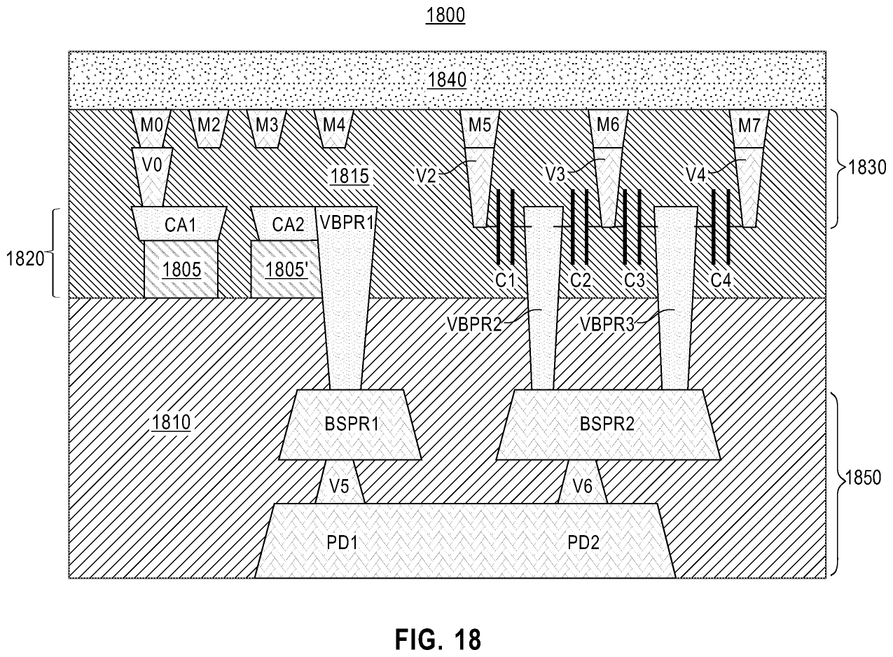

FIG. 18 illustrates a device 1800 that can be formed using one or more of the techniques described above and can take a structural form or utilize a structural element as described herein. The device 1800 include an FEOL region 1820 that can include one or more logic devices, e.g., transistors, associated with a semiconductor device or structure, a BEOL region 1840 that can include one or more interconnect devices or elements and/or other elements to complete one or more circuits and or finalize interconnection of all layers associated with device 1800, and MOL region 1830 for connecting the FEOL region 1820 and the BEOL region 1840 together, in addition to facilitating interoperability and/or connections between various elements of device 1800. In one or more embodiments, FEOL region 1820 includes regions 1805 and 1805′, which can be epitaxial layers or materials associated with a S/D region of a transistor device. As stated and implied, not all elements associated with FEOL region 1820, BEOL region 1840, and MOL region 1830 are shown.

In one or more embodiments of the present disclosure, BSPDN region 1850 can include one or more back-side power rails (BSPR1 and BSPR2) connected by one or more metal contacts, e.g., vias, V5 and V6 to one or more power delivery networks (PD1 and PD2). In one or more embodiments, BSPR1 and BSPR2 are considered a single rail because BSPR1 and BSPR2 can be formed during the same process or series of processes, even though BSPR1 and BSPR2 are disjointed. In one or more embodiments, BSPR1 and BSPR2 are considered separate rails or rail portions. In one or more embodiments, PD1 and PD2 are part of the same delivery network.

In one or more embodiments of the present disclosure, MOL region 1830 includes metal contacts M0, M2, M3, M4, M5, M6, and M7, and via contacts V0, V2, V3, and V4. In one or more embodiments, BEOL region 1840 includes various components (not shown) and elements (not shown), including interconnects (not shown) for completing one or more circuits in relation to device 1800.

In one or more embodiments, as shown, one or more capacitors (e.g., MIM capacitors) C1, C2, C3, and C4 are provided. As shown a via for backside power rail (VBPR), e.g., VBPR 2 and VBPR 3, is directly connected to at least one electrode of each of C1, C2, C3, and C4, while also being in direct contact with BSPR2 and providing an electrical connection to devices in FEOL region 1820 via at least one electrical path. In one or more embodiments, another electrode of C1, C2, C3, and C4 directly connects to at least one via V2, V3, and V4 of MOL region 1830, which in turn connects to BEOL region 1840 by contacts M5, M6, and M7 (e.g. M5, M6, and M7 directly contact an element of the BEOL region 1840).

In one or more embodiments, VBPR1 directly connects to a S/D region 1805′ by a contact area CA2 and directly connects to BSPR1. In one or more embodiments, at least one metal contact M0 of region 1830 connects to directly to a via V0 of region 1830 and directly to BEOL region 1840, and where via V0 directly connects by a contact area CA1 to S/D region 1805.

In one or more embodiments, at least two ILD layers are provided with respect to device 1800, ILD layer 1815 and BILD layer 1810, although each layer can be composed of additional dielectric layers, including other ILD layers in relation to unshown elements, and additional distinct ILD layers are consistent with the present disclosure.

Accordingly, in one or more embodiments, the structure of device 1800 provides for reduction of the impact of transient currents in a device 1800, while also providing multiple electrical paths to power devices, e.g., transistors, associated with FEOL region 1820 in the event of a power failure internally or otherwise.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a backside power rail (BSPR);
a source-drain (S/D) region connected to the BSPR; and
a metal-insulator-metal capacitor (MIMC),
wherein the BSPR directly connects to the MIMC by a MIMC via for backside power rail (VBPR) metal contact.

2. The semiconductor device of claim 1, wherein the MIMC VBPR contact is connected to at least one electrode of the MIMC.

3. The semiconductor device of claim 2, wherein the source-drain region is connected to the BSPR by a VBPR S/D metal contact.

4. The semiconductor device of claim 3, wherein the source-drain region is directly connected to the BSPR by the VBPR S/D metal contact.

5. The semiconductor device of claim 4, wherein the MIMC is in a dummy region of the semiconductor device.

6. The semiconductor device of claim 5, further comprising: a back-side power distribution network (BSPDN) directly connected with the BSPR.

7. The semiconductor device of claim 6, further comprising:
a middle-end-of-the-line (MOL) region including a plurality of metal contacts, wherein at least one electrode of the MMIMC directly coupled to at least one of the plurality of metal contacts of the MOL region.

8. The semiconductor device of claim 7, wherein the at least one MIMC electrode connected to the MIMC VBPR contact is distinct from the at least one electrode of the MIMC connected the at least one of the plurality of metal contacts of the MOL region.

9. The semiconductor device of claim 6, wherein:
the BSPR includes at least two portions;
the MIMC VBPR contacts at least one of the at least two portions of the BSPR; and
the VBPR S/D metal contacts another portion of the at least two portions of the BSPR.

10. A semiconductor device, comprising:
a back-end-of-the-line (BEOL) region;
a front-end-of-the-line (FEOL) region;
a backside power distribution network (BSPDN); and
a metal-insulator-metal (MIM) capacitor connected to both the BEOL region and the BSPDN region, wherein the MIM capacitor is directly connected to a via-buried-power-rail (VBPR) that in turn directly connects to the BSPDN.

11. The semiconductor device of claim 10, wherein the MIM capacitor is located in a distinct region of the semiconductor device than a region of the semiconductor device including one or more transistor devices.

12. The semiconductor device of claim 10, wherein the MIM capacitor is located in a dummy gate region of the semiconductor device.

13. The semiconductor device of claim 12, wherein the dummy gate region does not include a dummy gate.

14. A method of fabricating a semiconductor device, comprising:
providing a substrate;
forming one or more nanosheet stacks on the substrate, the one or more nanosheet stacks including at least one sacrificial layer and at least one semiconductor layer;
forming a plurality of dummy gates over the substrate, wherein a portion of the plurality of dummy gates form one or more dummy gate regions;
forming a plurality of spacers in contact with one or more sidewalls of the plurality of dummy gates;
removing the plurality of dummy gates and the plurality of spacers;
depositing a first metal layer and a dielectric layer in one or more recesses associated with the plurality of removed dummy gates;
after depositing the first metal layer and the dielectric layer, deposing a second metal layer over the dielectric layer in the one or more recesses; and
forming i) a plurality of middle-of-the-line (MOL) and back-end-of-the line (BEOL) contacts in contact with at least one of the first metal layer and the second metal layer and ii) one or more via for backside power rails (VBPRs) in contact with at least one of the first metal layer and the second metal layer.

15. The method according to claim 14 further comprising:
forming a back-side power rail (BSPR) that includes one or more portions, wherein a portion of the BSPR contacts at least one of the one or more VPBRs.

16. The method of claim 15 further comprising:
depositing a dielectric liner layer over a dielectric layer of a metal-insulator-metal (MIM) capacitor;
forming one or more shallow-trench isolation (STI) regions in relation to substrate, wherein the one or more shallow-trench isolation regions are each associated with at least one of the portion of the plurality of dummy gates of the one or more dummy gate regions; and
annealing the dielectric liner layer prior to depositing the second metal layer.

17. The method of claim 16 further comprising:
depositing a capping layer over the first metal layer prior to depositing the second metal layer; and
removing the capping layer prior to annealing the dielectric layer.

18. The method of claim 17 further comprising:
forming a gate region for the semiconductor device, wherein the second metal layer of the MIM capacitor and at least one metallic component of the gate region are formed during a same deposition process; and
annealing at least one gate region portion, wherein the annealing of the gate region portion and the annealing of the dielectric liner layer of the MIM capacitor is during a same annealing process.

19. The method of claim 18, the method further comprising:
forming a S/D region for the semiconductor device; and
forming a S/D VBPR in contact with at least one epitaxial layer of the S/D region, wherein the S/D VBPR is in contact with the at least one epitaxial layer of the S/D region and at least one portion of the BSPR contacts the S/D VPBR.

20. The method of claim 19, wherein the at least one portion of the BSPR contacting the S/D VBPR and the at least one portion of the BSPR contacting the one or more VBPRs in contact with the MIM capacitor VPBR are disjointed.
